(19) United States
(12) Patent Application Publication
(10) Pub. No.: US 2024/0282604 A1
(43) Pub. Date: Aug. 22, 2024

(54) SEMICONDUCTOR PROCESSING APPARATUS AND METHOD OF MANUFACTURING SEMICONDUCTOR DEVICE USING SEMICONDUCTOR PROCESSING APPARATUS

(71) Applicant: SAMSUNG ELECTRONICS CO., LTD., SUWON-SI (KR)

(72) Inventors: Sunwoo PARK, Seoul (KR); Minwoo RHEE, Suwon-si (KR); Sujie KANG, Suwon-si (KR); Bumki MOON, Suwon-si (KR); Seungdon LEE, Suwon-si (KR); Hyunjin LEE, Suwon-si (KR); Kyeongbin LIM, Suwon-si (KR)

(21) Appl. No.: 18/439,813

(22) Filed: Feb. 13, 2024

(30) Foreign Application Priority Data
Feb. 20, 2023 (KR) 10-2023-0022349

(51) Int. Cl. H01L 21/67; H01L 21/66

(52) U.S. Cl. CPC H01L 21/6715; H01L 21/67288; H01L 22/20

(57) ABSTRACT

A method of manufacturing a semiconductor device includes: performing a first semiconductor process on a semiconductor wafer including a front side and a back side opposing the front side; loading the semiconductor wafer into a semiconductor processing apparatus including a support, a spraying apparatus, and a warpage measuring apparatus, wherein the semiconductor wafer is supported by the support, wherein the spraying apparatus is disposed below the semiconductor wafer, and the warpage measuring apparatus is an apparatus configured to measure warpage of the semiconductor wafer; forming a warpage compensation pattern on the back side of the semiconductor wafer using the spraying apparatus until a warpage measurement value of the semiconductor wafer is within a predetermined range, while measuring warpage of the semiconductor wafer using the warpage measuring apparatus; and unloading, from the semiconductor processing apparatus, the semiconductor wafer on which the warpage compensation pattern is formed.

### CROSS-REFERENCE TO RELATED APPLICATION

This application claims priority under 35 U.S.C. § 119 to Korean Patent Application No. 10-2023-0022349 filed on Feb. 20, 2023 in the Korean Intellectual Property Office, the disclosure of which is incorporated by reference herein in its entirety.

### TECHNICAL FIELD

The present inventive concept relates to a semiconductor processing apparatus and a method of manufacturing a semiconductor device using the same.

### DISCUSSION OF THE RELATED ART

In accordance with a high degree of integration of semiconductor devices, semiconductor devices, including three-dimensionally arranged memory cells, have been under development. In semiconductor devices including three-dimensionally arranged memory cells, the three-dimensionally arranged memory cells are formed, and then warpage of a semiconductor wafer may be intensified, which may result in defects in a subsequent semiconductor process.

### SUMMARY

According to some example embodiments of the present inventive concept, a method of manufacturing a semiconductor device includes: performing a first semiconductor process on a semiconductor wafer, wherein the semiconductor wafer on which the first semiconductor process has been performed has a front side, on which an integrated circuit is formed, and a back side opposing the front side; loading the semiconductor wafer, on which the first semiconductor process has been performed, into a semiconductor processing apparatus including a support, a spraying apparatus, and a warpage measuring apparatus, wherein the semiconductor wafer is supported by the support, wherein the back side of the semiconductor wafer is positioned to face in a downward direction, wherein the spraying apparatus is disposed below the semiconductor wafer that is supported by the support, and the warpage measuring apparatus is an apparatus configured to measure warpage of the semiconductor wafer that is supported by the support; forming a warpage compensation pattern on the back side of the semiconductor wafer using the spraying apparatus until a warpage measurement value of the semiconductor wafer, which is measured by the warpage measuring apparatus, is within a predetermined range, while measuring warpage of the semiconductor wafer using the warpage measuring apparatus; and unloading, from the semiconductor processing apparatus, the semiconductor wafer on which the warpage compensation pattern is formed.

According to some example embodiments of the present inventive concept, a method of manufacturing a semiconductor device includes: performing a semiconductor process on a semiconductor wafer, wherein the semiconductor wafer on which the semiconductor process has been performed has a front side, on which an integrated circuit is formed, and a back side opposing the front side; loading the semiconductor wafer, on which the semiconductor process has been performed, into a semiconductor processing apparatus including a support, a warpage measuring apparatus, and a spraying apparatus, wherein the semiconductor wafer is supported by the support, wherein the back side of the semiconductor wafer is positioned to face in a downward direction, and wherein the spraying apparatus is disposed below the semiconductor wafer that is supported by the support; measuring warpage of the semiconductor wafer that is supported by the support by using the warpage measuring apparatus; forming a first warpage compensation pattern on the back side of the semiconductor wafer by spraying a warpage compensation material in a liquid phase onto the back side of the semiconductor wafer by using the spraying apparatus; measuring warpage of the semiconductor wafer on which the first warpage compensation pattern is formed by using the warpage measuring apparatus; and unloading, from the semiconductor processing apparatus, the semiconductor wafer on which the first warpage compensation pattern is formed, when a warpage measurement value of the semiconductor wafer on which the first warpage compensation pattern is formed, which is measured by the warpage measuring apparatus, is within a predetermined range.

According to some example embodiments of the present inventive concept, a semiconductor processing apparatus includes: a support configured to support a semiconductor wafer having a front side, on which an integrated circuit is formed, and a back side opposing the front side, wherein an edge region of the back side of the semiconductor wafer is disposed on the support; a spraying apparatus disposed below the semiconductor wafer that is supported by the support, wherein the spraying apparatus is configured to spray a warpage compensation material in a liquid phase toward a first region, among a plurality of regions of the back side of the semiconductor wafer; a warpage measuring apparatus configured to measure warpage of the semiconductor wafer that is supported by the support; and a controller configured to move the spraying apparatus to form a warpage compensation pattern reducing warpage of the semiconductor wafer, and to control spraying, from the spraying apparatus, of the warpage compensation material toward the first region, according to a warpage measurement value of the semiconductor wafer measured by the warpage measuring apparatus.

### BRIEF DESCRIPTION OF DRAWINGS

The above and other aspects of the present inventive concept will become more apparent by describing in detail example embodiments thereof, with reference to the accompanying drawings, in which:

FIGS. 1A, 1B, and 1C are diagrams illustrating examples of a semiconductor processing apparatus and a method of manufacturing a semiconductor device using the same according to an example embodiment of the present inventive concept;

FIG. 2 is a schematic diagram illustrating a modification of a semiconductor processing apparatus according to an example embodiment of the present inventive concept;

FIG. 3 is a schematic cross-sectional view illustrating a semiconductor wafer formed by a method of manufacturing a semiconductor device according to some example embodiments of the present inventive concept;

FIG. 4 is a schematic plan view illustrating a warpage compensation pattern formed by a method of manufacturing a semiconductor device according to some example embodiments of the present inventive concept;

FIGS. 5A and 5B are schematic plan views illustrating a method of forming a warpage compensation pattern in a method of manufacturing a semiconductor device according to some example embodiments of the present inventive concept;

FIG. 6 is a schematic plan view illustrating a modification of a warpage compensation pattern formed by a method of manufacturing a semiconductor device according to some example embodiments of the present inventive concept;

FIG. 7 is a schematic plan view illustrating a modification of a warpage compensation pattern formed by a method of manufacturing a semiconductor device according to some example embodiments of the present inventive concept;

FIG. 8 is a schematic plan view illustrating a modification of a warpage compensation pattern formed by a method of manufacturing a semiconductor device according to some example embodiments of the present inventive concept;

FIG. 9 is a schematic plan view illustrating a modification of a warpage compensation pattern formed by a method of manufacturing a semiconductor device according to some example embodiments of the present inventive concept;

FIG. 10 is a schematic plan view illustrating a modification of a warpage compensation pattern formed by a method of manufacturing a semiconductor device according to some example embodiments of the present inventive concept;

FIGS. 11 and 12 are schematic plan views illustrating a method of forming a warpage compensation pattern in a method of manufacturing a semiconductor device according to some example embodiments of the present inventive concept;

FIG. 13 is a schematic plan view illustrating a modification of a warpage compensation pattern formed by a method of manufacturing a semiconductor device according to some example embodiments of the present inventive concept;

FIG. 14 is a schematic plan view illustrating a modification of a warpage compensation pattern formed by a method of manufacturing a semiconductor device according to some example embodiments of the present inventive concept;

FIG. 15 is a schematic cross-sectional view illustrating a semiconductor wafer manufactured by a method of manufacturing a semiconductor device according to some example embodiments of the present inventive concept;

FIG. 16 is a schematic cross-sectional view illustrating a semiconductor wafer manufactured by a method of manufacturing a semiconductor device according to some example embodiments of the present inventive concept;

FIG. 17 is a schematic cross-sectional view illustrating a semiconductor wafer manufactured by a method of manufacturing a semiconductor device according to some example embodiments of the present inventive concept;

FIG. 18 is a schematic cross-sectional view illustrating a semiconductor wafer manufactured by a method of manufacturing a semiconductor device according to some example embodiments of the present inventive concept;

FIG. 19 is a schematic cross-sectional view illustrating a semiconductor wafer manufactured by a method of manufacturing a semiconductor device according to some example embodiments of the present inventive concept;

FIG. 20 is a schematic cross-sectional view illustrating a semiconductor wafer manufactured by a method of manufacturing a semiconductor device according to some example embodiments of the present inventive concept;

FIG. 21 is a schematic cross-sectional view illustrating a semiconductor wafer manufactured by a method of manufacturing a semiconductor device according to some example embodiments of the present inventive concept;

FIG. 22 is a schematic cross-sectional view illustrating a semiconductor wafer manufactured by a method of manufacturing a semiconductor device according to some example embodiments of the present inventive concept;

FIG. 23 is a schematic process flowchart illustrating a method of manufacturing a semiconductor device according to some example embodiments of the present inventive concept; and

FIGS. 24 and 25 are schematic diagrams illustrating a semiconductor device manufactured by a method of manufacturing a semiconductor device according to some example embodiments of the present inventive concept.

### DETAILED DESCRIPTION OF THE EMBODIMENTS

Hereinafter, for example, terms such as “upper portion,” “intermediate portion,” and “lower portion” may be replaced with other terms, for example, “first,” “second,” and “third” to describe elements of the specification. Terms such as “first,” “second,” and “third” may be used to describe different elements, but the elements are not limited by the terms, and a “first element” may be referred to as a “second element.”

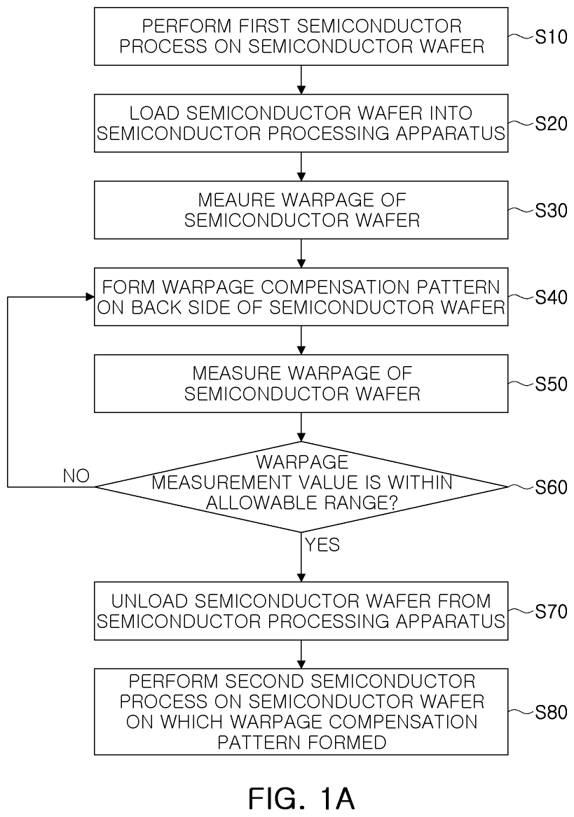

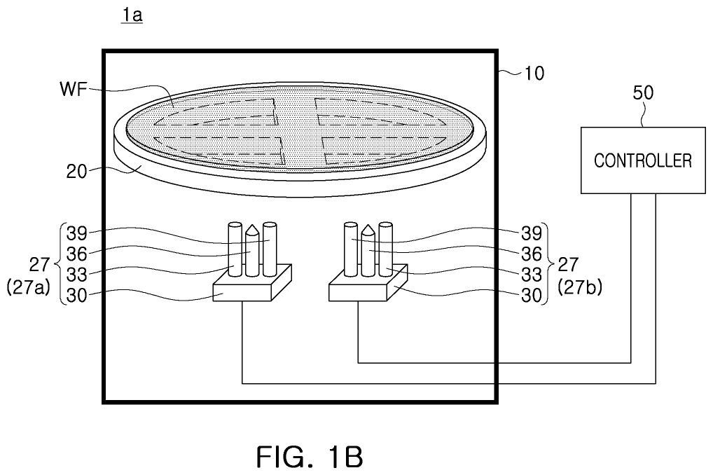

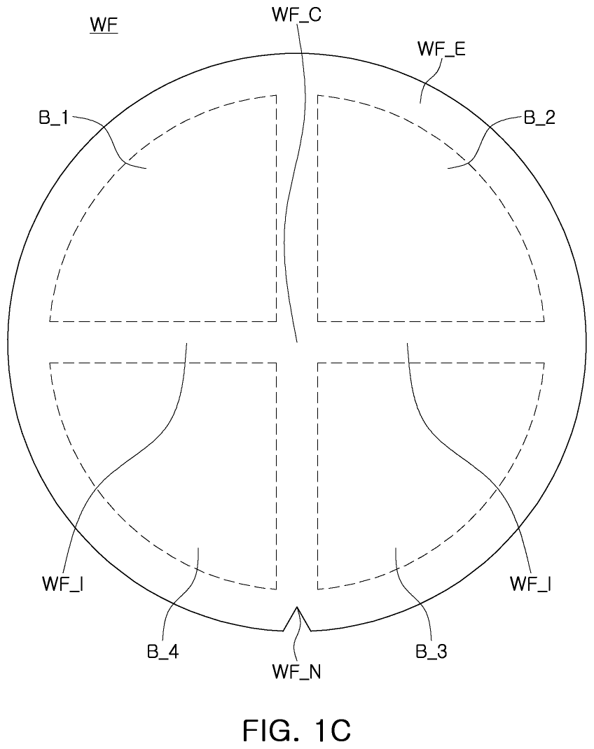

First, FIGS. 1A, 1B, and 1C illustrate a semiconductor processing apparatus and a semiconductor device manufacturing method using the same according to an example embodiment of the present inventive concept. In FIGS. 1A, 1B, and 1C, FIG. 1A is a schematic process flowchart illustrating a method of manufacturing a semiconductor device according to some example embodiments of the present inventive concept. FIG. 1B is a schematic diagram illustrating an example of a semiconductor processing apparatus according to an example embodiment of the present inventive concept, and FIG. 1C is a schematic plan view illustrating a back side of a semiconductor wafer to describe a method of manufacturing a semiconductor device according to some example embodiments of the present inventive concept.

Referring to FIGS. 1A, 1B, and 1C, a first semiconductor process may be performed on a semiconductor wafer WF (S10). The semiconductor wafer WF on which the first semiconductor process has been performed may be a wafer in which warpage may occur. For example, the semiconductor wafer WF on which the first semiconductor process has been performed may be in a state in which nonlinear warpage may occur.

A back side of the semiconductor wafer WF may have a plurality of regions B_1, B_2, B_3, and B_4. The back side of the semiconductor wafer WF may further have an edge region WF_E and a central region WF_C that is between the plurality of regions B_1, B_2, B_3, and B_4.

The back side of the semiconductor wafer WF may further have intermediate regions WF_I disposed between the plurality of regions B_1, B_2, B_3, and B_4 such that the plurality of regions B_1, B_2, B_3, and B_4 are spaced apart from each other, between the edge region WF_E and the central region WF_C.

The plurality of regions B_1, B_2, B_3, and B_4 may include a first region B_1, a second region B_2, a third region B_3, and a fourth region B_4. The semiconductor wafer WF may have a reference region WF_N such as a notch, a flat zone, a groove, an indentation or the like. The plurality of regions B_1, B_2, B_3, and B_4 may be divided using the reference region WF_N as a reference.

The semiconductor wafer WF may be loaded into a semiconductor processing apparatus 1a (S20).

The semiconductor processing apparatus 1a may include a support 20, a spraying apparatus 36, and a warpage measuring apparatus 33 within a processing chamber 10.

The semiconductor processing apparatus 1a may further include a curing apparatus 39 within the processing chamber 10.

The semiconductor processing apparatus 1a may further include a controller 50.

The support 20 may support the semiconductor wafer WF.

In an example, the support 20 may be in contact with the edge region WF_E of the back side of the semiconductor wafer WF, and may support the edge region WF_E of the semiconductor wafer WF.

In an example, the support 20 may include a central support portion extending up to a central region WF_C between the plurality of regions B_1, B_2, B_3, and B_4 from an edge support portion of the support 20 supporting the edge region WF_E of the back side of the semiconductor wafer WF. In FIG. 1C, a region indicated by WF_E may be supported by an edge support portion of the support 20, and regions indicated WF_I and WF_C may be supported by a central support portion of the support 20.

In an example, the warpage measuring apparatus 33 may be disposed on a level lower than that of the semiconductor wafer WF supported by the support 20.

In an example, the warpage measuring apparatus 33 may be a measuring apparatus using optics, but example embodiments of the present inventive concept are not limited thereto.

The spraying apparatus 36 may be disposed below the semiconductor wafer WF supported by the support 20. The spraying apparatus 36 may be a dispenser.

Warpage of the semiconductor wafer WF may be measured (S30). The warpage of the semiconductor wafer WF, supported by the support 20, may be measured by using the warpage measuring apparatus 33.

A warpage compensation pattern BCP may be formed on the back side of the semiconductor wafer WF (S40). According to a warpage measurement value of the semiconductor wafer WF measured by the warpage measuring apparatus 33, a warpage compensation material may be sprayed onto the back side of the semiconductor wafer WF, supported by the support 20, using the spraying apparatus 36 to form a warpage compensation pattern on the back side of the semiconductor wafer WF.

The warpage of the semiconductor wafer WF may be measured (S50). Here, the semiconductor wafer WF may be a semiconductor wafer on which the warpage compensation pattern is formed.

It may be determined whether the warpage measurement value is within an allowable range (S60). When the warpage measurement value is not within the allowable range, an operation (S40) of forming the warpage compensation pattern on the back side of the semiconductor wafer WF and an operation (S50) of measuring the warpage of the semiconductor wafer WF may be repeatedly performed until the warpage measurement value is within the allowable range.

A warpage compensation pattern that is initially formed on the back side of the semiconductor wafer WF may be defined as a first warpage compensation pattern. When the warpage measurement value is not within the allowable range after the first warpage compensation pattern is formed, a warpage compensation pattern may be continuously formed on the back side of the semiconductor wafer WF until the measurement value is within an allowable range. For example, additional warpage compensation patterns may be formed on the back side of the semiconductor wafer WF.

When the warpage measurement value is within the allowable range, the semiconductor wafer WF may be unloaded from the semiconductor processing apparatus 1a (S70). A second semiconductor process may be performed on the semiconductor wafer WF on which the warpage compensation pattern is formed (S80).

In an example embodiment of the present inventive concept, while the warpage of the semiconductor wafer WF is measured using the warpage measuring apparatus 33, the warpage compensation pattern may be formed on the back side BS of the semiconductor wafer WF by using the spraying apparatus 36 until the warpage measurement value of the semiconductor wafer WF, measured by the warpage measuring apparatus 33, is within the allowable range.

The warpage compensation material, sprayed onto the back side BS of the semiconductor wafer WF supported by the support 20 by using the spraying apparatus 36, may be sprayed in a liquid phase.

The warpage compensation material may include, for example, polyimide or a polyimide-based material.

The warpage compensation material may include, for example, a spin-on-hardmask (SOH) material.

The warpage compensation material may include, for example, a photo-imageable dielectric (PID) material.

The warpage compensation material may be sprayed onto the back side BS of the semiconductor wafer WF in a liquid phase.

The warpage compensation material, sprayed onto the back side BS of the semiconductor wafer WF, may be adhered to the back side BS of the semiconductor wafer WF and may be then cured. For example, the warpage compensation material, sprayed onto the back side BS of the semiconductor wafer WF, may be cured by the curing apparatus 39 on the back side BS of the semiconductor wafer WF, and thus may be formed as the warpage compensation pattern that is in contact with the back side BS of the semiconductor wafer WF to reduce the warpage of the semiconductor wafer WF.

The spraying apparatus 36 may be configured to three-dimensionally move along an X-axis, a Y-axis, and a Z-axis of an X-Y-Z coordinate system, to spray the warpage compensation material onto the back side BS of the semiconductor wafer WF supported by the support 20.

In an example, the warpage measuring apparatus 33 may be configured to move together with the spraying apparatus 36. For example, the warpage measuring apparatus 33 and the spraying apparatus 36 may be attached or connected to each other and may be connected to a track on which the warpage measuring apparatus 33 and the spraying apparatus 36 may move; however, the present inventive concept is not limited thereto.

In an example, the curing apparatus 39 may be configured to move together with the spraying apparatus 36. For example, the curing apparatus 39 and the spraying apparatus 36 may be attached or connected to each other and may be connected to a track on which the curing apparatus 39 and the spraying apparatus 36 may move; however, the present inventive concept is not limited thereto.

In an example, the curing apparatus 39 may be a UV curing apparatus or an infrared curing apparatus, but example embodiments of the present inventive concept are not limited thereto.

In an example, the semiconductor processing apparatus 1a may further include a base 30 simultaneously moving the warpage measuring apparatus 33, the spraying apparatus 36, and the curing apparatus 39. For example, the base 30 may be on a track or rail on which the base 30 may move. The warpage measuring apparatus 33, the spraying apparatus 36, the curing apparatus 39, and the base 30 may be included in a module 27.

In an example, the module 27 may be disposed in plurality. For example, the module 27 may include a first module 27a and a second module 27b.

Each of the first and second modules 27a and 27b may include the spraying apparatus 36. Accordingly, a plurality of spraying apparatuses, for example, first and second spraying apparatuses 36, may be disposed below the semiconductor wafer WF that is supported by the support 20. The first and second spraying apparatuses 36 may spray the warpage spraying material onto different regions, among the plurality of regions B_1, B_2, B_3, and B_4 of the back side BS of the semiconductor wafer WF.

The first spraying apparatus 36 of the first module 27a may spray the warpage compensation material onto the first region B_1 of the back side BS of the semiconductor wafer WF from below the first region B_1 of the back side BS of the semiconductor wafer WF. The second spraying apparatus 36 of the second module 27b may spray the warpage compensation material onto the third region B_3 of the back side BS of the semiconductor wafer WF from below the third region B_3 of the back side of the semiconductor wafer WF. The warpage compensation pattern may include a first warpage compensation pattern, which is formed by the first spraying apparatus 36 of the first module 27a, and a second warpage compensation pattern, which is formed by the second spraying apparatus 36 of the second module 27b.

According to the warpage measurement value of the semiconductor wafer WF measured by the warpage measuring apparatus 33, the controller 50 may be configured to move the spraying apparatus 36 along an X-axis, a Y-axis, and a Z-axis of an X-Y-Z coordinate system to form a warpage compensation pattern that reduces the warpage of the semiconductor wafer WF, and to control spraying of the warpage compensating material toward one region, among the plurality of regions B_1, B_2, B_3, and B_4 of the back side BS of the semiconductor wafer WF.

The first and second modules 27a and 27b may be independently moved and may be independently controlled, by the controller 50.

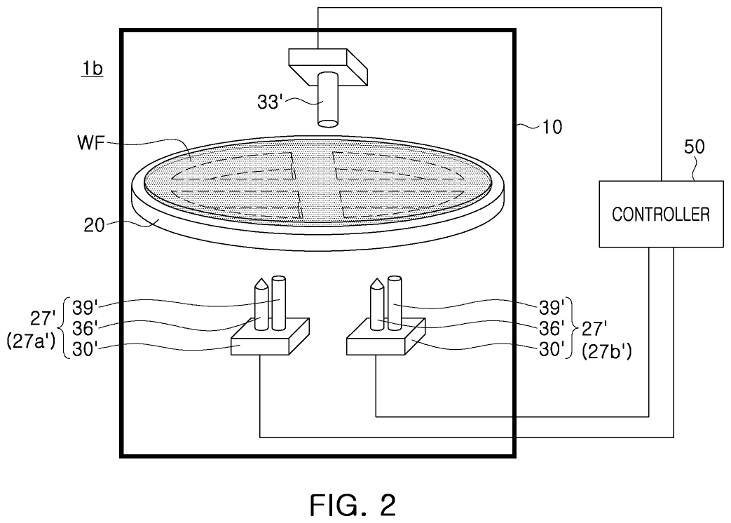

The warpage measuring apparatus 33 may be disposed on a level lower than that of the semiconductor wafer WF that is supported by the support 20, but example embodiments of the present inventive concept are not limited thereto. Hereinafter, referring to FIG. 2, a warpage measuring apparatus 33′, disposed above the semiconductor wafer WF that is supported by the support 20, will be described. FIG. 2 is a schematic diagram illustrating a modification of a semiconductor processing apparatus according to an example embodiment of the present inventive concept.

Referring to FIG. 2, the warpage measuring apparatus (33 in FIG. 1B), disposed on a level lower than that of the semiconductor wafer WF that is supported by the support 20 described with reference to FIG. 1, may be replaced with the warpage measuring apparatus 33′, disposed above the semiconductor wafer WF. Accordingly, the module 27 in FIG. 1B may be replaced with a module 27′ in which the warpage measuring apparatus (33 in FIG. 1B) is omitted. The module 27′ may include first and second modules 27a′ and 27b′, which are independently moved and independently controlled, and each of the first and second modules 27a′ and 27b′ may include a base 30′, corresponding to the base 30, and a spraying apparatus 36′, corresponding to the spraying apparatus 36. Each of the first and second modules 27a′ and 27b′ may further include a curing apparatus 39′, corresponding to the curing apparatus 39.

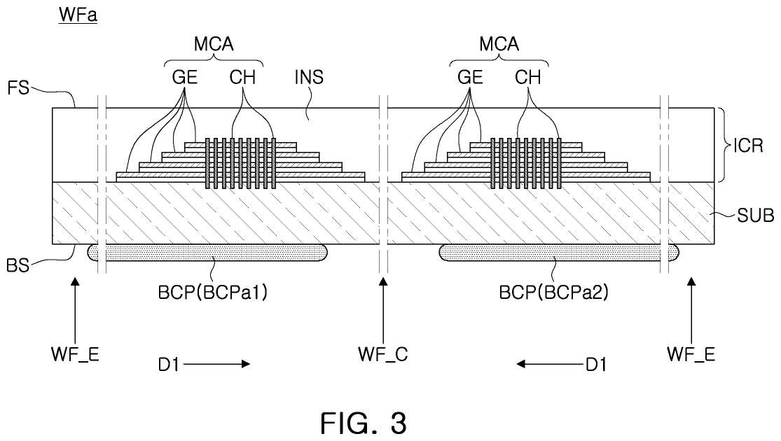

Next, with reference to FIG. 3, an example of the semiconductor wafer WF described above will be described. FIG. 3 is a schematic cross-sectional view illustrating a cross-sectional structure of a semiconductor wafer according to an example embodiment of the present inventive concept.

Referring to FIG. 3, a semiconductor wafer WFa according to an example embodiment of the present inventive concept may include a substrate SUB and an integrated circuit region ICR on the substrate SUB. The semiconductor wafer WFa may have a front side FS on which the integrated circuit region ICR is formed and a back side BS opposing the front side FS.

The integrated circuit region ICR may include a plurality of memory cell array regions MCA on the substrate SUB, and an insulating structure INS covering the plurality of memory cell array regions MCA on the substrate SUB.

Each of the plurality of memory cell array regions MCA may include gate electrodes GE, vertically stacked and spaced apart from each other, and vertical channel structures CH passing through the gate electrodes GE. Each of the plurality of memory cell array regions MCA may include three-dimensionally arranged memory cells.

By the operation (S40) of forming the warpage compensation pattern on the back side BS of the semiconductor wafer (WF in FIG. 1B) described with reference to FIG. 1A, the warpage compensation pattern BCP, described with reference to FIG. 1A, may be formed on the back side BS of the semiconductor wafer WFa. Accordingly, the semiconductor wafer WFa may include the warpage compensation pattern BCP.

The semiconductor wafer WFa may have an edge region WF_E and a central region WF_C, as described with reference to FIG. 1C.

In FIG. 3, a direction of DI may refer to a direction extending away from the edge region WF_E and toward an inner region of the semiconductor wafer WFa.

The warpage compensation pattern BCP may include a first-side warpage compensation pattern BCPa1 and a second-side warpage compensation pattern BCPa2, that are spaced apart from each other.

The warpage compensation pattern BCP may be disposed between the edge region WF_E and the central region WF_C.

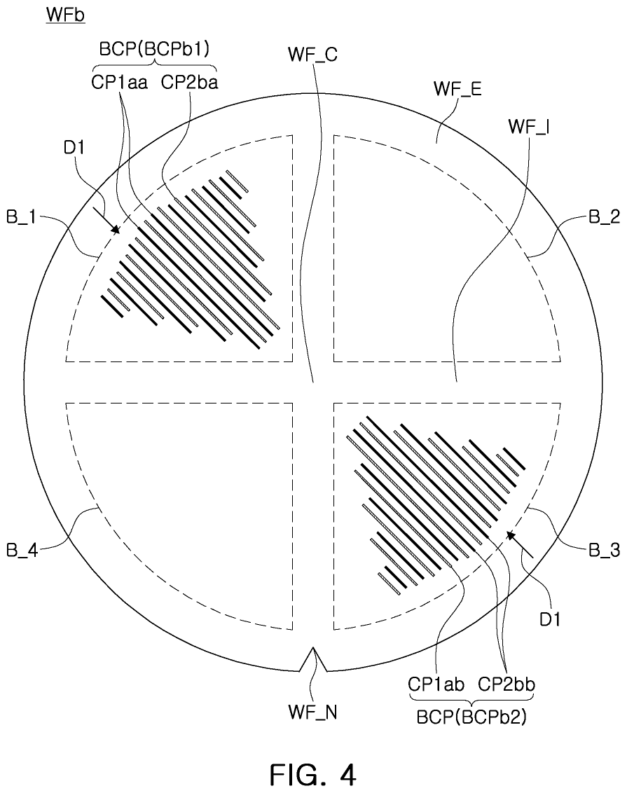

Next, with reference to FIG. 4, an example of the warpage compensation pattern BCP described above will be described. FIG. 4 is a plan view illustrating a back side of a semiconductor wafer WFb, including a warpage compensation pattern, formed by a method of manufacturing a semiconductor device according to some example embodiments of the present inventive concept.

Referring to FIG. 4 together with FIGS. 1A, 1B, 1C, and 3, the first-side warpage compensation pattern BCPa1 in FIG. 3 may be formed as a first-side warpage compensation pattern BCPb1 including first and second warpage compensation patterns CP1aa and CP2ba formed in the first region B_1, and the second-side warpage compensation pattern BCPa2 in FIG. 3 may be formed as a second-side warpage compensation pattern BCPb2 including first and second warpage compensation patterns CP1ab and CP2bb formed in the third region B_3.

In some example embodiments of the present inventive concept, the terms “first-side warpage compensation pattern” and “second-side warpage compensation pattern” may be used to distinguish warpage compensation patterns formed in different regions, among the plurality of regions B_1, B_2, B_3, and B_4 of the back side of the semiconductor wafer WF.

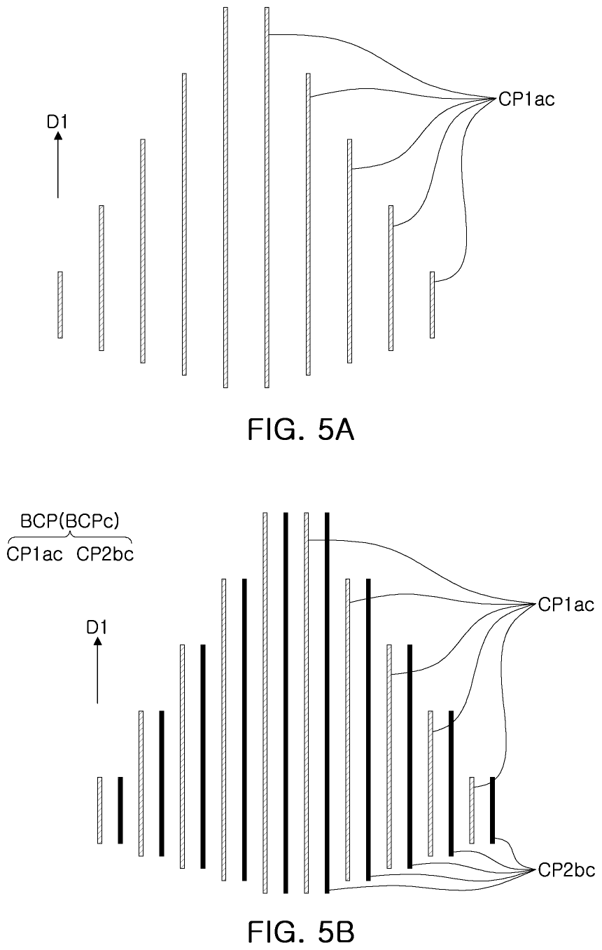

An example of a method of forming the first and second warpage compensation patterns CP1aa and CP2ba of the first-side warpage compensation pattern BCPb1 and/or the first and second warpage compensation patterns CP1ab and CP2bb of the second-side warpage compensation pattern BCPb2 will be described with reference to FIGS. 5A and 5B. FIG. 5A is a schematic plan view illustrating a first warpage compensation pattern formed first, among the warpage compensation patterns BCP, and FIG. 5B is a schematic plan view illustrating a second warpage compensation pattern formed later, among the warpage compensation patterns BCP.

Referring to FIGS. 5A and 5B together with FIGS. 1A, 1B, 1C, 3, and 4, according to a warpage measurement value of the semiconductor wafer WF measured by the warpage measuring apparatus 33, a warpage compensation material may be sprayed onto the back side of the semiconductor wafer WF that is supported by the support 20 by using the spraying apparatus 36 to form a warpage compensation pattern CP1ac on the back side BS of the semiconductor wafer WF.

Warpage of the semiconductor wafer WF on which the first warpage compensation pattern CP1ac is formed may be measured.

When the warpage measurement value of the semiconductor wafer WF on which the first warpage compensation pattern CP1ac is formed is outside of an allowable range, according to the warpage measurement value of the semiconductor wafer WF on which the first warpage compensation pattern CP1ac is formed, which is measured by the warpage measuring apparatus 33, the warpage compensation material may be sprayed onto the back side BS of the semiconductor wafer WF by using the spraying apparatus 36 to form a second warpage compensation pattern CP2bc on the back side BS of the semiconductor wafer WF.

Accordingly, a warpage compensation pattern BCPc, including the first and second warpage compensation patterns CP1ac and CP2bc, may be formed on the back side BS of the semiconductor wafer WF.

In some example embodiments of the present inventive concept, the terms “first warpage compensation pattern” and “second warpage compensation pattern” refer to may refer to elements included in a warpage compensation pattern formed in one region, among the plurality of regions B_1, B_2, B_3, and B_4 of the back side BS of the semiconductor wafer WF.

In some example embodiments of the present inventive concept, in one region among the plurality of regions B_1, B_2, B_3, and B_4 of the back side BS of the semiconductor wafer WF, the term “first warpage compensation pattern” may refer to a warpage compensation pattern formed first, and the term “second warpage compensation pattern” may refer to a warpage compensation pattern formed later.

In an example, the first warpage compensation pattern CP1ac may include line portions extending in the direction of D1 (e.g., a first direction) from the edge region WF_E to the central region WF_C.

In an example, the second warpage compensation pattern CP2bc may include line portions extending in the direction of D1.

In an example, the line portions of the second warpage compensation pattern CP2bc may be disposed between the line portions of the first warpage compensation pattern CP1ac. For example, the second warpage compensation pattern CP2bc and the first warpage compensation pattern CP1ac may be alternately arranged.

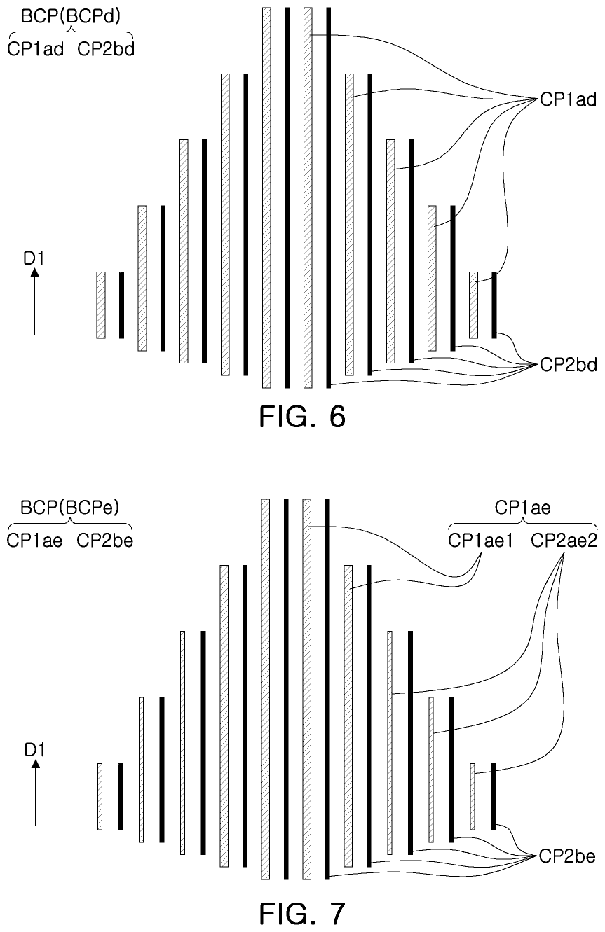

In an example, the line portions of the second warpage compensation pattern CP2bc and the line portions of the first warpage compensation pattern CP1ac may have the same width as each other, but example embodiments of the present inventive concept are not limited thereto. Hereinafter, various modifications of the line portions of the second warpage compensation pattern CP2bc and the line portions of the first warpage compensation pattern CP1ac will be described with reference to FIGS. 6, 7, 8, and 9.

FIGS. 6, 7, 8, and 9 are plan views illustrating various modifications of the warpage compensation pattern BCP described above, respectively.

According to an example embodiment of the present inventive concept, referring to FIG. 6, a warpage compensation pattern BCPd may include a first warpage compensation pattern CP1ad having line portions and a second warpage compensation pattern CP2bd having line portions. A width of at least one of the line portions of the second warpage compensation pattern CP2bd may be narrower than a width of at least one of the line portions of the first warpage compensation pattern CP1ad.

According to an example embodiment of the present inventive concept, referring to FIG. 7, a warpage compensation pattern BCPe may include a first warpage compensation pattern CP1ae having line portions CP1ae1 and CP1ae2 and a second warpage compensation pattern CP2be having line portions. The line portions CP1ae1 and CP1ae2 of the first warpage compensation pattern CP1ae may include first line portions CP1ae1 having a first width and second line portions CP1ae2 having a second width narrower than the first width. The first line portions CP1ae1 may be disposed between the second line portions CP1ae2.

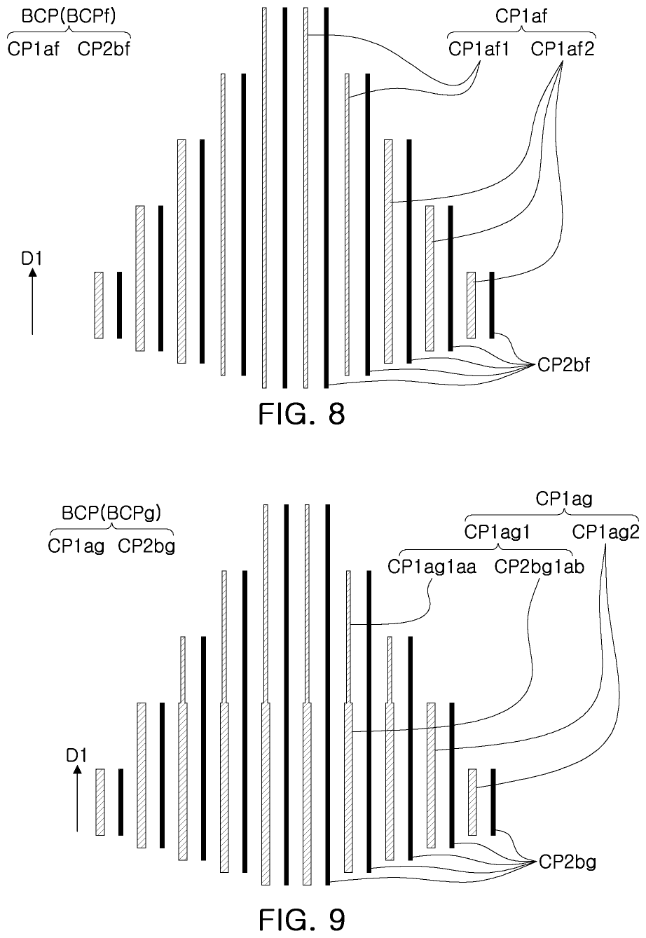

According to an example embodiment of the present inventive concept, referring to FIG. 8, a warpage compensation pattern BCPf may include a first warpage compensation pattern CP1af having line portions CP1af1 and CP1af2 and a second warpage compensation pattern CP2bf having line portions. The line portions CP1af1 and CP1af2 of the first warpage compensation pattern CP1af may include first line portions CP1af1 having a first width and second line portions CP1af2 having a second width wider than the first width. The first line portions CP1af1 may be disposed between the second line portions CP1af2.

According to an example embodiment of the present inventive concept, referring to FIG. 9, the warpage compensation pattern BCPg may include a first warpage compensation pattern CP1ag, which includes line portions CP1ag1 and CP1ag2, and a second warpage compensation pattern CP2bg having line portions. The line portions CP1ag1 and CP1ag2 of the first warpage compensation pattern CP1ag may include first line portions CP1ag1, each of which has portions CPag1aa and CP2bg1ab with different widths from each other, and second line portions CP1ag2, each of which has a constant width.

Each of the first warpage compensation pattern CP1ag1 may include a first portion CP2bg1ab, which has a first width, and a second portion CP1ag1aa, which has a second width wider than the first width.

To effectively reduce the warpage of the semiconductor wafer, the first portion CP2bg1ab may be disposed to be closer to the edge region WF_E than the second portion CP1ag1aa.

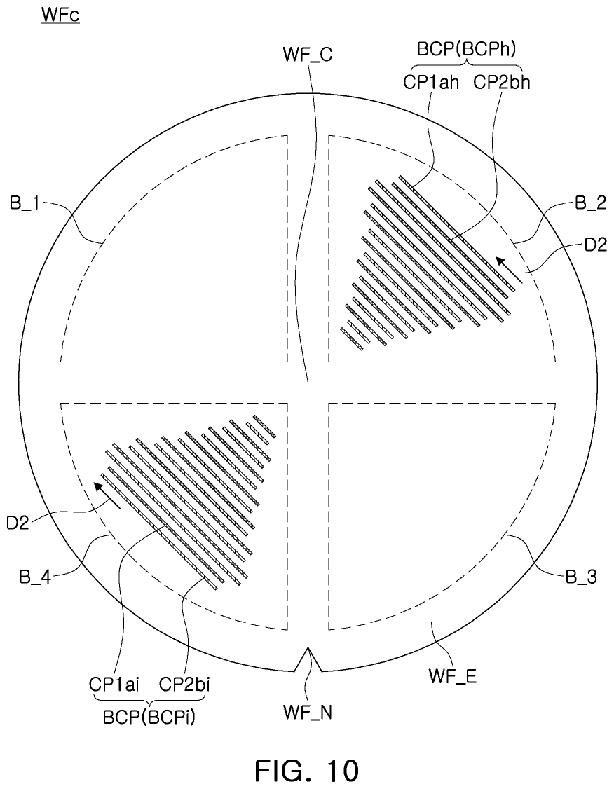

The warpage compensation pattern BCP described above with reference to FIGS. 3, 4, 5A, 5B, 6, 7, and 9 may include line portions extending in the direction of D1, but example embodiments of the present inventive concept are not limited thereto. Hereinafter, an example of a compensation pattern including line portions extending in a direction of D2, which is substantially perpendicular to the direction of D1, will be described with reference to FIGS. 10, 11, and 12. FIG. 10 is a plan view illustrating a back side of a semiconductor wafer WFc including a warpage compensation pattern formed by a method of manufacturing a semiconductor device according to some example embodiments of the present inventive concept.

Referring to FIG. 10 together with FIGS. 1A, 1B, 1C, and 3, the first-side warpage compensation pattern BCPa1 in FIG. 3 may be formed as a first-side warpage compensation pattern BCPh, including first and second warpage compensation patterns CP1ah and CP2bh, formed in the second region B_2, and the second-side warpage compensation pattern BCPa2 in FIG. 3 may be formed as a second-side warpage compensation pattern BCPi, including first and second warpage compensation patterns CP1ai and CP2bi, formed in the fourth region B_4.

In some example embodiments of the present inventive concept, the terms “first-side warpage compensation pattern” and “second-side warpage compensation pattern” may be used to distinguish warpage compensation patterns from each other that are formed in different regions, among the plurality of regions B_1, B_2, B_3, and B_4 of the back side of the semiconductor wafer WF.

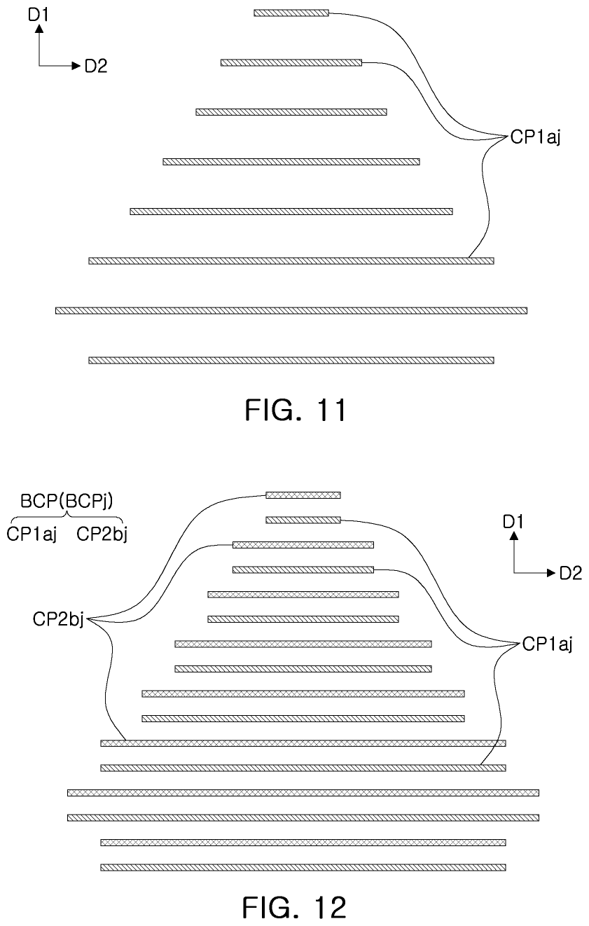

An example of a method of forming the first and second warpage compensation patterns CP1ah and CP2bh of the first-side warpage compensation pattern BCPh and/or the first and second warpage compensation patterns CP1ai and CP2bi of the second-side warpage compensation pattern BCPi will be described with reference to FIGS. 10 and 11. FIG. 11 is a schematic plan view illustrating a first warpage compensation pattern formed first, among the warpage compensation patterns BCP, and FIG. 12 is a schematic plan view illustrating a second warpage compensation pattern formed after the first warpage compensation pattern, among the warpage compensation patterns BCP.

Referring to FIGS. 11 and 12 together with FIGS. 1A, 1B, 1C, 3, and 10, according to a warpage measurement value of the semiconductor wafer WF measured by the warpage measuring apparatus 33, a warpage compensation material may be sprayed onto the back side BS of the semiconductor wafer WF, which is supported by the support 20, by using the spraying apparatus 36 in the second direction D2 to form a first warpage compensation pattern CP1aj on the back side BS of the semiconductor wafer WF. Warpage of the semiconductor wafer WF on which the first warpage compensation pattern CP1aj is formed may be measured. When the warpage measurement value of the semiconductor wafer WF on which the first warpage compensation pattern CP1aj is formed is outside of an allowable range, according to the warpage measurement value of the semiconductor wafer WF on which the first warpage compensation pattern CP1aj is formed, the warpage compensation material may be sprayed onto the back side BS of the semiconductor wafer WF by using the spraying apparatus 36 in the second direction D2 to form a second warpage compensation pattern CP2bj on the back side BS of the semiconductor wafer WF.

Accordingly, a warpage compensation pattern BCPj, including the first and second warpage compensation patterns CP1aj and CP2bj, may be formed on the back side BS of the semiconductor wafer WF.

In an example, the first warpage compensation pattern CP1aj may include line portions extending in the direction of D2 (e.g., a second direction).

In an example, the second warpage compensation pattern CP2bj may include line portions extending in the direction of D2.

In an example, the line portions of the second warpage compensation pattern CP2bj may be disposed between the line portions of the first warpage compensation pattern CP1aj. For example, the line portions of the second warpage compensation pattern CP2bj may be alternately arranged with the line portions of the first warpage compensation pattern CP1aj.

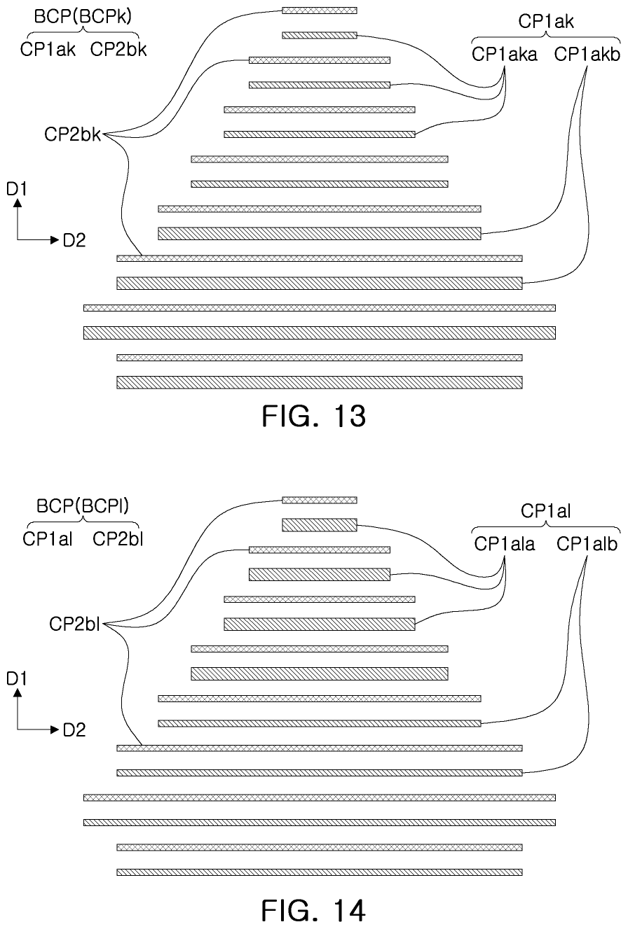

In an example, the line portions of the second warpage compensation pattern CP2bj and the line portions of the first warpage compensation pattern CP1aj may have the same width as each other, but example embodiments of the present inventive concept are not limited thereto. Hereinafter, various modifications of the warpage compensation pattern BCPj will be described with reference to FIGS. 13 and 14, respectively. FIGS. 13 and 14 are plan views illustrating various modifications of the warpage compensation pattern BCP described above, respectively.

According to an embodiment of the present inventive concept, referring to FIG. 13, a warpage compensation pattern BCPk may include a first warpage compensation pattern CP1ak, which has line portions CP1aka and CP1akb extending in the second direction D2, and a second warpage compensation pattern CP2bk, which has line portions extending in the second direction D2. The line portions CP1aka and CP1akb of the first warpage compensation pattern CP1ak may include first line portions CP1aka, which has a first width, and second line portions CP1akb, which has a second width narrower than the first width. The first line portions CP1aka may be disposed between the second line portions CP1akb. A length of at least one of the first line portions CP1aka may be longer than a length of at least one of the second line portions CP1akb.

According to an example embodiment of the present inventive concept, referring to FIG. 14, a warpage compensation pattern BCPl may include a first warpage compensation pattern CP1al, which has line portions CP1ala and CP1alb extending in the second direction D2, and a second warpage compensation pattern CP2bl, which has line portions extending in the second direction D2. The line portions CP1ala and CP1alb of the first warpage compensation pattern CP1al may include first line portions CP1ala, which has a first width, and second line portions CP1alb, which has a second width narrower than the first width. The first line portions CP1ala may be disposed between the second line portions CP1alb. A length of at least one of the first line portions CP1ala may be shorter than a length of at least one of the second line portions CP1alb.

Among the warpage compensation patterns BCP formed according to the example embodiments described above with reference to FIGS. 1A to 14, a warpage compensation pattern according to some example embodiments of the present inventive concept may include line portions having the same width as each other or line portions having different widths from each other. Among the warpage compensation patterns BCP formed according to the example embodiments described above with reference to FIGS. 1A to 14, at least one of line portions of the warpage compensation pattern according to some example embodiments may have regions having different widths from each other. Thus, the warpage compensation pattern BCP formed according to the example embodiments described above with reference to FIGS. 1A to 14 may include line portions having the same width as each other, line portions having different widths from each other, or line portions having different width regions from each other.

The warpage compensation pattern BCP formed according to the example

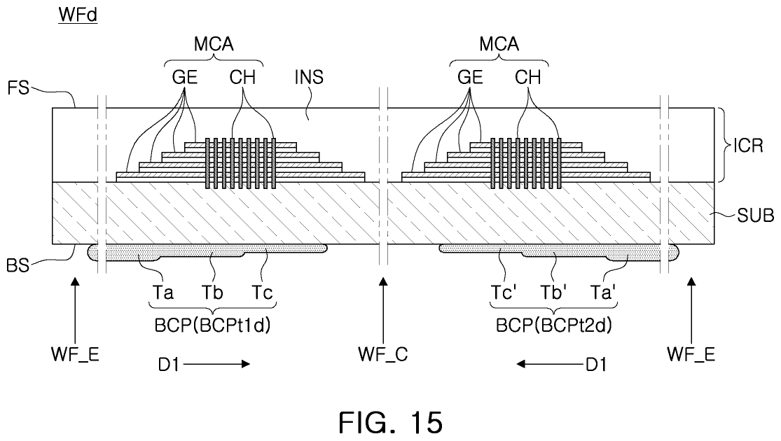

embodiments described above with reference to FIGS. 1A to 14 may have substantially the same thickness as each other, but the example embodiments of the present inventive concept are not limited thereto. Hereinafter, with reference to FIGS. 15, 16, 17, 18, and 19, various thickness modifications of the warpage compensation pattern BCP formed according to the example embodiments described above with reference to FIGS. 1A to 14 will be described. FIGS. 15, 16, 17, 18 and 19 are cross-sectional views illustrating a semiconductor wafer including the warpage compensation pattern BCP.

According to an example embodiment of the present inventive concept, referring to FIG. 15, the first and second warpage compensation patterns BCPa1 and BCPa2, formed on the back side BS of the semiconductor wafer WFa described with reference to FIG. 3, may be modified into first and second warpage compensation patterns BCPt1d and BCPt2d, illustrated in

FIG. 15. Each of the first and second warpage compensation patterns BCPt1d and BCPt2d may have a linear shape extending in the direction of D1. At least one of the first and second warpage compensation patterns BCPt1d and BCPt2d may include portions having different thicknesses from each other.

The first warpage compensation pattern BCPt1d may include a first thickness portion Ta, a second thickness portion Tb, and a third thickness portion Tc, sequentially arranged in the direction of D1. The first thickness portion Ta may be larger than the second thickness portion Tb, and the second thickness portion Tb may be larger than the third thickness portion Tc. The second warpage compensation pattern BCPt2d may include a first thickness portion Ta′, a second thickness portion Tb′, and a third thickness portion Tc′, sequentially arranged in the direction of D1. The first thickness portion Ta′ may be larger than the second thickness portion Tb′, and the second thickness portion Tb′ may be larger than the third thickness portion Tc′. Accordingly, a semiconductor wafer WFd, including the first and second warpage compensation patterns BCPt1d and BCPt2d, may be provided.

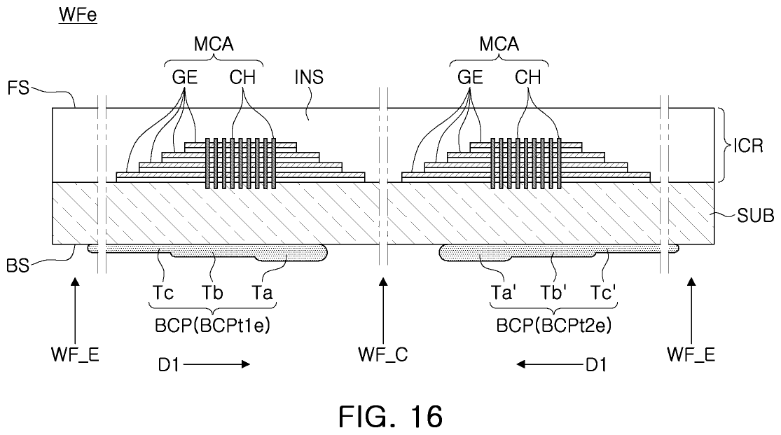

According to an example embodiment of the present inventive concept, referring to FIG. 16, the first and second warpage compensation patterns BCPa1 and BCPa2, formed on the back side BS of the semiconductor wafer WFa described with reference to FIG. 3, may be modified into first and second warpage compensation patterns BCPt1e and BCPt2e, illustrated in FIG. 16. Each of the first and second warpage compensation patterns BCPt1e and BCPt2e may have a linear shape extending in the direction of D1. The first warpage compensation pattern BCPt1e may include a third thickness portion Tc, a second thickness portion Tb, and a first thickness portion Ta, sequentially arranged in the direction of D1. The first thickness portion Ta may be greater than the second thickness portion Tb, and the second thickness portion Tb may be greater than the third thickness portion Tc. The second warpage compensation pattern BCPt2e may include a third thickness portion Tc′, a second thickness portion Tb′, and a first thickness portion Ta′, sequentially arranged in the direction of D1. The first thickness portion Ta′ may be larger than the second thickness portion Tb′, and the second thickness portion Tb′ may be larger than the third thickness portion Tc′. Accordingly, a semiconductor wafer WFde, including the first and second warpage compensation patterns BCPt1e and BCPt2e, may be provided.

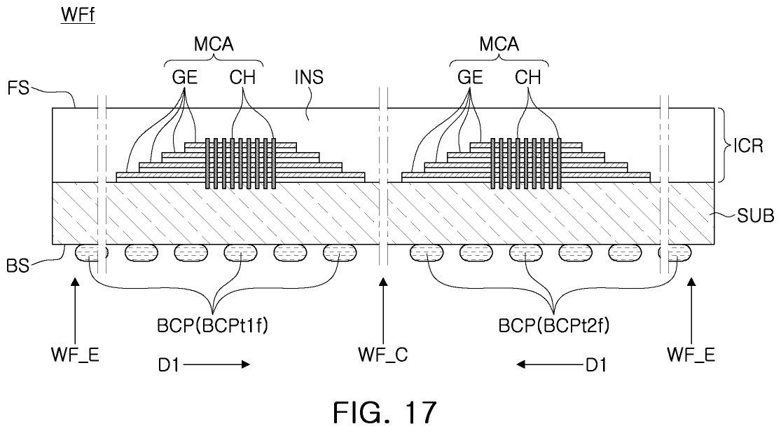

According to an example embodiment of the present inventive concept, referring to FIG. 17, the first and second warpage compensation patterns BCPa1 and BCPa2, formed on the back side BS of the semiconductor wafer WFa described with reference to FIG. 3, may be modified into first and second warpage compensation patterns BCPt1f and BCPt2f, illustrated in FIG. 17. Each of the first and second warpage compensation patterns BCPt1f and BCPt2f may include portions spaced apart from each other in the direction of DI. Accordingly, a semiconductor wafer WFf, including the first and second warpage compensation patterns BCPt1f and BCPt2f, may be provided.

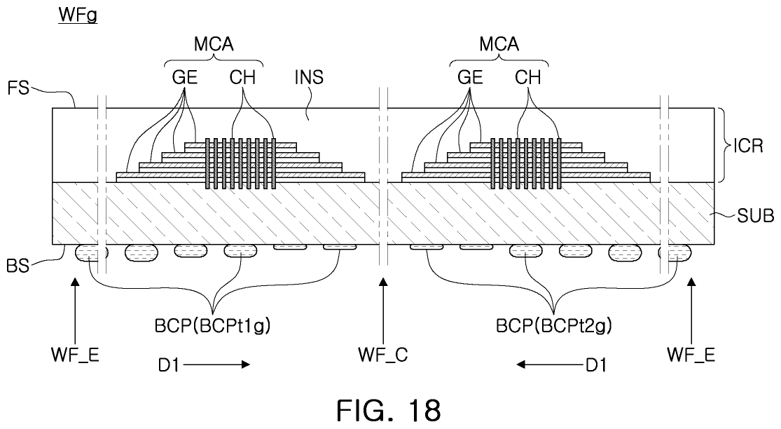

According to an example embodiment of the present inventive concept, referring to FIG. 18, the first and second warpage compensation patterns BCPa1 and BCPa2, described with reference to FIG. 17, may be modified into first and second warpage compensation patterns BCPt1g and BCPt2g, illustrated in FIG. 18. In each of the first and second warpage compensation patterns BCPt1g and BCPt2g, at least some of portions, spaced apart from each other in the direction of D1, may have different thicknesses from each other. For example, in each of the first and second warpage compensation patterns BCPt1g and BCPt2g, portions, which are spaced apart from each other in the direction of D1, may have smaller thickness in a region close to the central region WF_C, and may have a larger thickness in a region far away from the central region WF_C. For example, the portions of the first and second warpage compensation patterns BCPt1g and BCPt2g that are closest to the central region WF_C have a thickness that is smaller than the thickness of the portions of the first and second warpage compensation patterns BCPt1g and BCPt2g that are farthest from the central region WF_C. For example, the thicknesses of the portions of the first and second warpage compensation patterns BCPt1g and BCPt2g may decrease as the central region WF_C is approached. Accordingly, a semiconductor wafer WFg, including the first and second warpage compensation patterns BCPt1g and BCPt2g, may be provided.

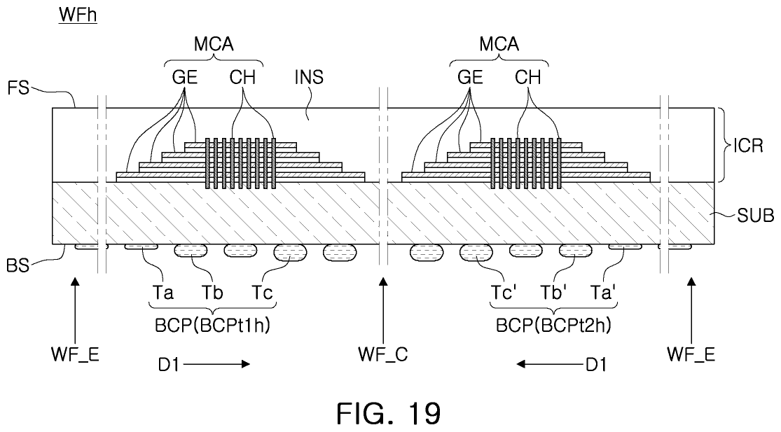

According to an example embodiment of the present inventive concept, referring to FIG. 19, the first and second warpage compensation patterns BCPa1 and BCPa2, described with reference to FIG. 17, may be modified into first and second warpage compensation patterns BCPt1h and BCPt2h, illustrated in FIG. 19. In each of the first and second warpage compensation patterns BCPt1h and BCPt2h, portions, spaced apart from each other in the direction of D1, have a larger thickness in a region close to the central region WF_C, and may have a smaller thickness in a region far away from the central region WF_C. For example, each of the first and second warpage compensation patterns BCPt1h and BCPt2h may include first thickness portions Ta and Ta′, second thickness portions Tb and Tb′, and the third thickness portions Tc and Tc′, sequentially arranged in the direction of D1. The third thickness portions Tc and Tc′ may be thicker than the second thickness portions Tb and Tb′, and the second thickness portions Tb and Tb′ may be thicker than the first thickness portions Ta and Ta′.

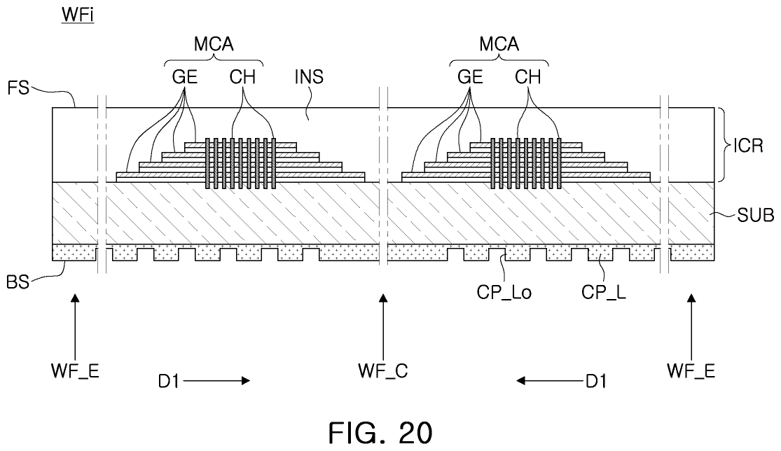

A semiconductor wafer WF, according to an example embodiment of the present inventive concept, before forming the various types of warpage compensation patterns BCP described above with reference to FIGS. 3 to 20 will be described with reference to FIG. 20. FIG. 20 is a schematic cross-sectional view illustrating a cross-sectional structure of a semiconductor wafer according to an example embodiment of the present inventive concept.

Referring to FIG. 20, a semiconductor wafer WFi may include the substrate SUB and the integrated circuit region ICR on the substrate SUB, which may substantially the same as those described above with reference to FIG. 3.

The semiconductor wafer WFi may further include a back side reinforcement pattern CP_L below the substrate SUB.

The back side reinforcement pattern CP_L may be formed of an insulating material. For example, the back side reinforcement pattern CP_L may be formed of silicon oxide. For example, the back side reinforcement pattern CP_L may include tetraethoxysilane oxide (TEOS). The back side reinforcement pattern CP_L may have grooves CP_Lo. The grooves CP_Lo may be opening in a downward direction. A back side BS of the semiconductor wafer WFi may be a lower surface of the back side reinforcement pattern CP_L.

The semiconductor wafer WFi may be a semiconductor wafer before the warpage compensation pattern is formed thereon. For example, the semiconductor wafer WFi may be a semiconductor wafer in a state in which the first semiconductor process in operation S10 described with reference to FIG. 1A is performed.

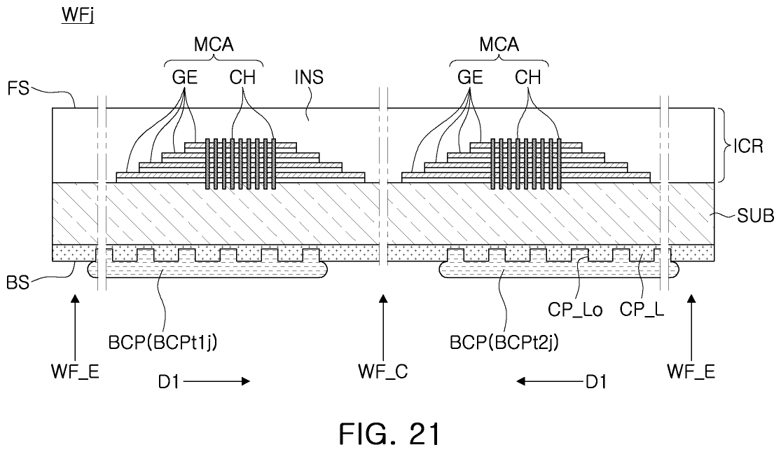

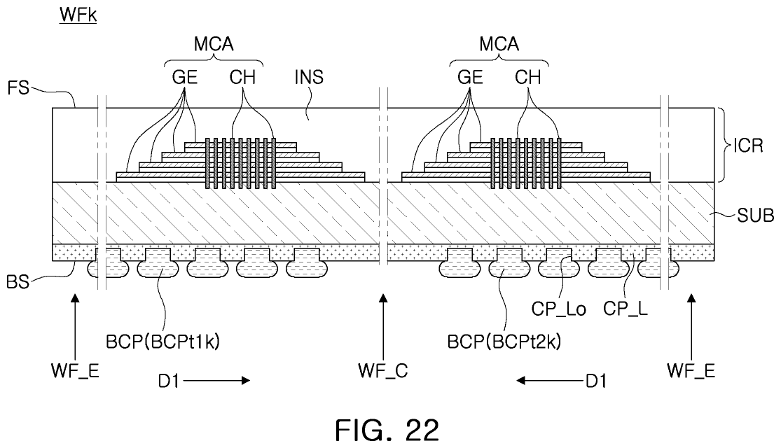

Next, an example in which the warpage compensation pattern BCP described above is formed on the semiconductor wafer WFi in FIG. 20 will be described with reference to each of FIGS. 21 and 22. FIG. 21 is a cross-sectional view illustrating a semiconductor wafer WFj obtained by forming, on the semiconductor wafer WFi in FIG. 20, the warpage compensation pattern BCP, which has a linear shape extending in the direction of D1, among the above-described example embodiments. FIG. 22 is a cross-sectional view illustrating a semiconductor wafer WFk obtained by forming, on the semiconductor wafer WFi in FIG. 20, the warpage compensation pattern BCP, which includes portions spaced apart from each other in the direction of D1, among the above-described example embodiments.

In an example, referring to FIGS. 20 and 21, the semiconductor wafer WFj may be formed on the back side BS of the semiconductor wafer WFi in FIG. 20, and may include a warpage compensation pattern BCP, having a linear shape extending in the direction of D1, among the above-described example embodiments.

The warpage compensation pattern BCP may include first and second warpage compensation patterns BCPt1j and BCPt2j respectively extending in the direction of D1. At least a portion of the first and second warpage compensation patterns BCPt1j and BCPt2j may cover the lower surface of the back side reinforcement pattern CP_L while filling at least a portion of the grooves CP_Lo of the back side reinforcement pattern CP_L.

In an example, referring to FIGS. 20 and 22, the semiconductor wafer WFk may be formed on the back side BS of the semiconductor wafer WFi in FIG. 20, and may include a warpage compensation pattern BCP, having portions spaced apart from each other in the direction of D1, among the above-described example embodiments. The warpage compensation pattern BCP may include first and second warpage compensation patterns BCPt1k and BCPt2k, which respectively include portions spaced apart from each other in the direction of D1. At least a portion of the first and second warpage compensation patterns BCPt1k and BCPt2k may cover the lower surface of the back side reinforcement pattern CP_L while filling at least a portion of the grooves CP_Lo of the back side reinforcement pattern CP_L.

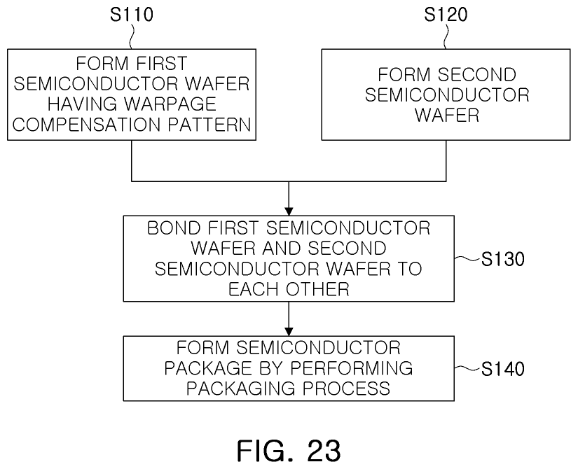

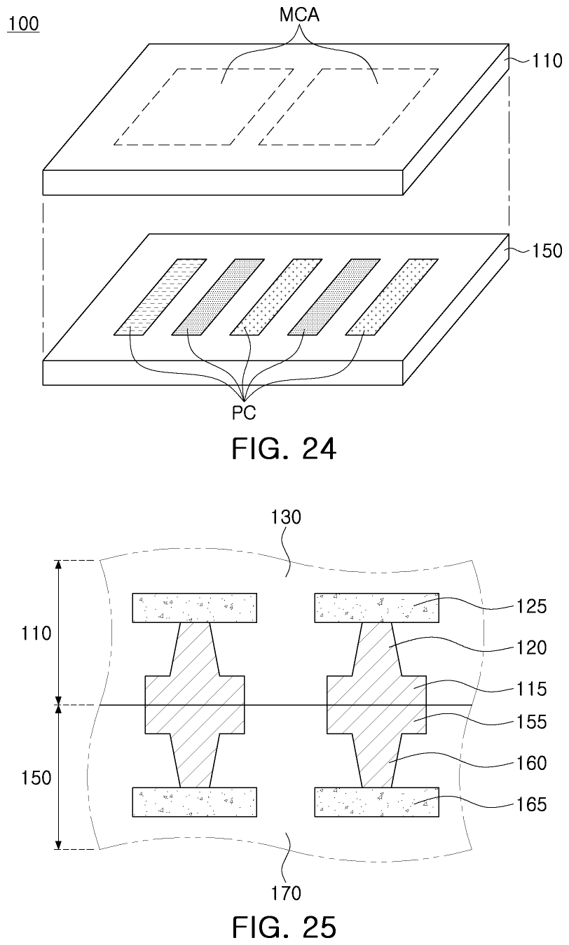

A method of manufacturing a semiconductor device using a semiconductor wafer including the warpage compensation pattern BCP described above, and a semiconductor device manufactured by the method will be described with reference to FIGS. 23, 24, and 25. FIG. 23 is a process flowchart illustrating a method of manufacturing a semiconductor device using a semiconductor wafer including the warpage compensation pattern BCP described above, according to an example embodiment of the present inventive concept. FIG. 24 is a schematic perspective view illustrating a semiconductor device manufactured by a method of manufacturing a semiconductor device using a semiconductor wafer including the warpage compensation pattern BCP, according to an example embodiment of the present inventive concept. FIG. 25 is a schematic partially enlarged cross-sectional view illustrating a bonding region between a lower semiconductor chip and an upper semiconductor chip of the semiconductor device of FIG. 24, according to an example embodiment of the present inventive concept.

Referring to FIGS. 23, 24, and 25, a first semiconductor wafer, having a warpage compensation pattern, may be formed (S110). The warpage compensation pattern may be a warpage compensation pattern BCP according to one of the above-described example embodiments. For example, the first semiconductor wafer may be the semiconductor wafer (WFa in FIG. 3) illustrated in FIG. 3 or the semiconductor wafer WFk illustrated in FIG. 22, but the example embodiments of the present inventive concept are not limited thereto. The first semiconductor wafer may be a memory semiconductor wafer including memory cell array regions MCA. Each of the memory cell array regions MCA may include three-dimensionally arranged memory cells.

A second semiconductor wafer may be formed (S120). The second semiconductor wafer may be, for example, a logic semiconductor wafer including a peripheral circuit region PC.

In an example, the second semiconductor wafer may include the warpage compensation pattern BCP according to one of the above-described example embodiments.

In an example, the second semiconductor wafer might not include the warpage compensation pattern BCP according to one of the above-described example embodiments.

The first semiconductor wafer and the second semiconductor wafer may be bonded to each other (S130). Bonding the first semiconductor wafer and the second semiconductor wafer to each other may include performing an inter-metal bonding process.

A semiconductor package may be formed by performing a packaging process (S140). The packaging process may include a back grinding process of reducing a thickness of each of the first and second semiconductor wafers that are bonded to each other and a cutting process of separating the first and second semiconductor wafers that are bonded to each other into a plurality of semiconductor chips. During the packaging process, the warpage compensation pattern BCP may be removed. The plurality of semiconductor chips may be formed into a semiconductor package. Thus, the semiconductor device 100, in the form of a semiconductor package, may be formed.

The semiconductor device 100 may include a lower semiconductor chip 150 and an upper semiconductor chip 110 that is disposed on the lower semiconductor chip 150. The upper semiconductor chip 110 may include a plurality of memory cell array regions MCA. The memory cell array regions MCA may be the memory cell array regions MCA in FIG. 3. The memory cell array regions MCA may include three-dimensionally arranged memory cells.

The lower semiconductor chip 150 may include a peripheral circuit region PC capable of operating the memory cell array regions MCA. For example, the peripheral circuit region PC may be used to operate the memory cell array regions MCA.

In a bonding region between the lower semiconductor chip 150 and the upper semiconductor chip 110, the lower semiconductor chip 150 may include a lower bonding pad 155, a lower connection via 160 disposed below the lower bonding pad 155, a lower interconnection structure 165 disposed below the lower connection via 160, and a lower insulating structure 170 covering the lower bonding pad 155, the lower connection via 160, and the lower interconnection structure 165. An upper surface of the lower insulating structure 170 may be substantially coplanar with an upper surface of the lower bonding pad 155.

In a bonding region between the lower semiconductor chip 150 and the upper semiconductor chip 110, the upper semiconductor chip 110 may include an upper bonding pad 115, an upper connection via 1120 disposed on the upper bonding pad 115, an upper interconnection structure 125 disposed on the upper connection via 120, and an upper insulating structure 130 covering the upper bonding pad 115, the upper connection via 120, and the upper interconnection structure 125. A lower surface of the upper insulating structure 130 may be substantially coplanar with a lower surface of the upper bonding pad 115.

The upper insulating structure 130 and the lower insulating structure 170 may be bonded to each other while being in contact with each other. The upper bonding pad 115 and the lower bonding pad 155 may be bonded to each other while being in contact with each other. The upper bonding pad 115 and the lower bonding pad 155 may include the same metal material as each other, for example, copper (Cu).

In an example embodiment of the present inventive concept, in an operation (S130) of bonding the first semiconductor wafer and the second semiconductor wafer to each other, the first semiconductor wafer including three-dimensionally arranged memory cells may be a semiconductor wafer having warpage reduced by the warpage compensation pattern BCP, such that the upper bonding pad 115 and the lower bonding pad 155 may be bonded to each other without defects.

According to some example embodiments of the present inventive concept, a method of forming a warpage compensation pattern on a back side of a semiconductor wafer while measuring warpage of the semiconductor wafer may be provided. The warpage compensation pattern may be formed by spraying a warpage compensation material onto the back side of the semiconductor wafer in a liquid phase. The warpage compensation pattern may be formed on at least a portion of the back side of the semiconductor wafer.

According to some example embodiments of the present inventive concept, to form the warpage compensation pattern on the back side of the semiconductor wafer, a semiconductor processing apparatus, including a spraying apparatus spraying a warpage spraying material in a liquid phase, a warpage measuring apparatus measuring warpage of the semiconductor wafer, and a controller, may be provided.

The warpage compensation pattern, formed by the semiconductor processing apparatus and the method using the semiconductor processing apparatus, may reduce warpage of the semiconductor wafer, thereby reducing defects in a semiconductor process.

While the present inventive concept has been described with reference to embodiments thereof, it will be understood by those of ordinary skill in the art that various changes in form and details may be made thereto without departing from the spirit and scope of the present inventive concept.

What is claimed is:

1. A method of manufacturing a semiconductor device, the method comprising:
performing a first semiconductor process on a semiconductor wafer, wherein the semiconductor wafer on which the first semiconductor process has been performed has a front side, on which an integrated circuit is formed, and a back side opposing the front side;
loading the semiconductor wafer, on which the first semiconductor process has been performed, into a semiconductor processing apparatus including a support, a spraying apparatus, and a warpage measuring apparatus, wherein the semiconductor wafer is supported by the support, wherein the back side of the semiconductor wafer is positioned to face in a downward direction, wherein the spraying apparatus is disposed below the semiconductor wafer that is supported by the support, and the warpage measuring apparatus is an apparatus configured to measure warpage of the semiconductor wafer that is supported by the support;
forming a warpage compensation pattern on the back side of the semiconductor wafer using the spraying apparatus until a warpage measurement value of the semiconductor wafer, which is measured by the warpage measuring apparatus, is within a predetermined range, while measuring warpage of the semiconductor wafer using the warpage measuring apparatus; and
unloading, from the semiconductor processing apparatus, the semiconductor wafer on which the warpage compensation pattern is formed.

2. The method of claim 1,
wherein the forming the warpage compensation pattern on the back side of the semiconductor wafer includes spraying a warpage compensation material onto the back side of the semiconductor wafer by using the spraying apparatus that is disposed below the semiconductor wafer, and
wherein the warpage compensation material, which is sprayed onto the back side of the semiconductor wafer by the spraying apparatus, is sprayed in a liquid phase.

3. The method of claim 2,
wherein the semiconductor processing apparatus further includes a curing apparatus, and
wherein the warpage compensation material in the liquid phase, which is sprayed onto the back side of the semiconductor wafer by the spraying apparatus, is adhered to the back side of the semiconductor wafer, and is cured by the curing apparatus to form the warpage compensation pattern.

4. The method of claim 1, wherein the warpage compensation pattern includes a first portion, which has a first thickness, and a second portion, which has a second thickness wider than the first thickness.

5. The method of claim 1, wherein the warpage compensation pattern includes a first compensation pattern portion, which has a first width, and a second compensation pattern portion, which has a second width wider than the first width.

6. The method of claim 1, wherein the warpage compensation pattern includes line portions extending parallel to each other.

7. The method of claim 1,
wherein the semiconductor processing apparatus further includes a second spraying apparatus disposed below the semiconductor wafer supported by the support,
wherein the back side of the semiconductor wafer has a plurality of regions,
wherein the regions include a first region and a second region,
wherein the spraying apparatus includes:
a first spraying apparatus configured to spray a warpage compensation material onto the first region of the back side of the semiconductor wafer from below the first region of the back side of the semiconductor wafer; and
a second spraying apparatus configured to spray the warpage compensation material onto the second region of the back side of the semiconductor wafer from below the second region of the back side of the semiconductor wafer, and
wherein the warpage compensation pattern includes a first warpage compensation pattern, which is formed by the first spraying apparatus, and a second warpage compensation pattern, which is formed by the second spraying apparatus.

8. The method of claim 1,
wherein the back side of the semiconductor wafer has a plurality of regions, and
wherein the regions include a region in which the warpage compensation pattern is formed and a region in which the warpage compensation pattern is not formed.

9. A method of manufacturing a semiconductor device, the method comprising:
performing a semiconductor process on a semiconductor wafer, wherein the semiconductor wafer on which the semiconductor process has been performed has a front side, on which an integrated circuit is formed, and a back side opposing the front side;
loading the semiconductor wafer, on which the semiconductor process has been performed, into a semiconductor processing apparatus including a support, a warpage measuring apparatus, and a spraying apparatus, wherein the semiconductor wafer is supported by the support, wherein the back side of the semiconductor wafer is positioned to face in a downward direction, and wherein the spraying apparatus is disposed below the semiconductor wafer that is supported by the support;
measuring warpage of the semiconductor wafer that is supported by the support by using the warpage measuring apparatus;
forming a first warpage compensation pattern on the back side of the semiconductor wafer by spraying a warpage compensation material in a liquid phase onto the back side of the semiconductor wafer by using the spraying apparatus;
measuring warpage of the semiconductor wafer on which the first warpage compensation pattern is formed by using the warpage measuring apparatus; and
unloading, from the semiconductor processing apparatus, the semiconductor wafer on which the first warpage compensation pattern is formed, when a warpage measurement value of the semiconductor wafer on which the first warpage compensation pattern is formed, which is measured by the warpage measuring apparatus, is within a predetermined range.

10. The method of claim 9,
wherein the semiconductor wafer includes a back side reinforcement pattern formed on the back side thereof, wherein the back side reinforcement pattern has grooves, and
wherein the warpage compensation material, which is sprayed onto the back side of the semiconductor wafer by using the spraying apparatus, fills at least a portion of the grooves of the back side reinforcement pattern, is adhered to the back side of the semiconductor wafer, and is cured on the back side reinforcement pattern.

11. The method of claim 9, wherein the warpage compensation material includes polyimide or a polyimide-based material.

12. The method of claim 9,
wherein the semiconductor processing apparatus further includes a curing apparatus,
wherein the method further includes curing the warpage compensation material sprayed onto the back side of the semiconductor wafer, using the curing apparatus, after spraying the warpage compensation material onto the back side of the semiconductor wafer,
wherein the warpage compensation material is sprayed onto the back side of the semiconductor wafer in the liquid phase, and
wherein the warpage compensation material is cured on the back side of the semiconductor wafer by the curing apparatus to form the first warpage compensation pattern.

13. The method of claim 9, further comprising:
after forming the first compensation pattern on the back side of the semiconductor wafer and when the warpage measurement value of the semiconductor wafer is outside of the predetermined range, forming a second warpage compensation pattern on the back side of the semiconductor wafer by spraying the warpage compensation material onto the back side of the semiconductor wafer by using the spraying apparatus; and
measuring warpage of the semiconductor wafer on which the first and second warpage compensation patterns are formed, using the warpage measuring apparatus.

14. The method of claim 13, further comprising:
unloading, from the semiconductor processing apparatus, the semiconductor wafer, on which the first and second warpage compensation patterns are formed, when the warpage measurement value of the semiconductor wafer, on which the first and second warpage compensation patterns are formed, which is measured by the warpage measuring apparatus, is within the predetermined range.

15. The method of claim 9, wherein the warpage measuring apparatus is configured to move together with the spraying apparatus, and to measure warpage of the semiconductor wafer.

16. The method of claim 9, wherein the warpage measuring apparatus is at a higher level than the semiconductor wafer that is supported by the support, and is configured to measure warpage of the semiconductor wafer.

17. A method of manufacturing a semiconductor device, the method comprising:
measuring warpage of a semiconductor wafer using a semiconductor processing apparatus; and
forming a warpage compensation pattern on a back side of the semiconductor wafer using the semiconductor processing apparatus until a warpage measurement value of the semiconductor wafer, which is measured by the semiconductor processing apparatus, is within a predetermined range, while measuring warpage of the semiconductor wafer using the semiconductor processing apparatus,
wherein the semiconductor processing apparatus includes:
a support configured to support the semiconductor wafer having a front side, on which an integrated circuit is formed, and the back side opposing the front side, wherein an edge region of the back side of the semiconductor wafer is disposed on the support;
a spraying apparatus disposed below the semiconductor wafer that is supported by the support, wherein the spraying apparatus is configured to spray a warpage compensation material in a liquid phase toward a first region, among a plurality of regions of the back side of the semiconductor wafer;
a warpage measuring apparatus configured to measure warpage of the semiconductor wafer that is supported by the support; and
a controller configured to move the spraying apparatus to form a warpage compensation pattern reducing warpage of the semiconductor wafer, and to control spraying, from the spraying apparatus, of the warpage compensation material toward the first region, according to a warpage measurement value of the semiconductor wafer measured by the warpage measuring apparatus.

18. The method of claim 17,
wherein the semiconductor processing apparatus further includes a curing apparatus,
wherein the method further includes curing the warpage compensation material sprayed onto the back side of the semiconductor wafer, using the curing apparatus, after spraying the warpage compensation material onto the back side of the semiconductor wafer,
wherein the warpage compensation material is sprayed onto the back side of the semiconductor wafer in the liquid phase, and
wherein the warpage compensation material is cured on the back side of the semiconductor wafer by the curing apparatus to form the first warpage compensation pattern.

19. The method of claim 17, wherein the warpage measuring apparatus is positioned above the semiconductor wafer that is supported by the support.

20. The method of claim 17, wherein the spraying apparatus includes:
a first spraying apparatus configured to spray the warpage compensation material toward the first region; and
a second spraying apparatus configured to spray the warpage compensation material toward a second region among the plurality of regions of the back side of the semiconductor wafer.
